(19) United States
(12) Patent Application Publication
(10) Pub. No.: US 2014/0325150 A1
(43) Pub. Date: Oct. 30, 2014

(54) WIRELESS APPARATUS

(71) Applicant: KABUSHIKI KAISHA TOSHIBA, Tokyo (JP)

(72) Inventors: Koh Hashimoto, Yokohama-shi (JP); Yukako Tsutsumi, Kawasaki-shi (JP); Takayoshi Ito, Yokohama-shi (JP)

(73) Assignee: KABUSHIKI KAISHA TOSHIBA, Tokyo (JP)

(21) Appl. No.: 14/182,633

(22) Filed: Feb. 18, 2014

(30) Foreign Application Priority Data
Apr. 30, 2013 (JP) 2013-095710

(51) Int. Cl. H01L 23/552

(52) U.S. Cl. CPC H01L 23/552
USPC 711/115; 257/659

(57) ABSTRACT

According to one embodiment, a wireless apparatus includes a substrate, a first semiconductor chip, a transmission line, a non-conductive layer, a conductive layer and a wire. The first semiconductor chip is arranged on the substrate and includes a circuit which transmits and receives a signal. The transmission line includes a first portion which is formed in at least one of the substrate and the first semiconductor chip. The non-conductive layer seals the first semiconductor chip. The conductive layer covers a surface of the non-conductive layer, an opening being formed in at least a part of the conductive layer. The wire is connected to the first portion so as to extend from the first portion toward the opening and is arranged in a position in which the opening is excited.

### CROSS-REFERENCE TO RELATED APPLICATIONS

This application is based upon and claims the benefit of priority from Japanese Patent Application No. 2013-095710, filed Apr. 30, 2013, the entire contents of which are incorporated herein by reference.

### FIELD

Embodiments described herein relate generally to a wireless apparatus.

### BACKGROUND

As wireless electronic devices are downsized and made high density packaging, in addition to using a high frequency used in the devices, interference caused by radiation of unnecessary electromagnetic waves becomes a problem. Thus leakage of unnecessary electromagnetic waves to the outside needs to be reduced.

Shielding is an example of a general method for suppressing unnecessary electromagnetic waves from a semiconductor package. There is an approach to coat a surface of a non-conductive resin layer, which seals a semiconductor chip with a conductive resin layer in order to add a shielding function to a semiconductor package. There is also proposed a module with a built-in antenna including an opening in a non-conductive resin layer which seals a semiconductor, and a part of a conductive resin layer which covers an upper surface of the semiconductor chip, thereby achieving a shielding effect against unnecessary electromagnetic waves, and which is capable of transmitting and receiving desired waves used for communications.

### BRIEF DESCRIPTION OF THE DRAWINGS

FIG. 1A illustrates a wireless apparatus according to a first embodiment.

FIG. 1B is a cross-sectional view illustrating the wireless apparatus according to the first embodiment.

FIG. 1C is a cross-sectional view illustrating an arrangement example of a bonding wire of the wireless apparatus according to the first embodiment.

FIG. 2A illustrates a wireless apparatus according to a second embodiment.

FIG. 2B is a cross-sectional view illustrating the wireless apparatus according to the second embodiment.

FIG. 3A illustrates another example of the wireless apparatus according to the second embodiment.

FIG. 3B is a cross-sectional view illustrating another example of the wireless apparatus according to the second embodiment.

FIG. 4A illustrates a wireless apparatus according to a third embodiment.

FIG. 4B is a cross-sectional view illustrating the wireless apparatus according to the third embodiment.

FIG. 5A illustrates a wireless apparatus according to a fourth embodiment.

FIG. 5B is a cross-sectional view illustrating the wireless apparatus according to the fourth embodiment.

FIG. 6A illustrates a wireless apparatus according to a fifth embodiment.

FIG. 6B is a cross-sectional view illustrating the wireless apparatus according to the fifth embodiment.

FIG. 7A illustrates another example of the wireless apparatus according to the fifth embodiment.

FIG. 7B is a cross-sectional view illustrating another example of the wireless apparatus according to the fifth embodiment.

FIG. 8A illustrates a wireless apparatus according to a sixth embodiment.

FIG. 8B is a cross-sectional view illustrating the wireless apparatus according to the sixth embodiment.

FIG. 9 is a block diagram illustrating a wireless system according to a seventh embodiment.

FIG. 10 is a block diagram illustrating an example of the wireless system including a wireless apparatus.

FIG. 11 illustrates an example of the wireless system in which a wireless apparatus is mounted on a memory card.

### DETAILED DESCRIPTION

In the above-described approach, since the semiconductor chip, which becomes the source of noise, and the opening formed in the conductive resin are close to each other, the shielding effect against unnecessary electromagnetic waves deteriorates. When an opening is formed in a position apart from a semiconductor chip so as to reduce deterioration of the shielding effect, on the other hand, since the distance between an antenna-feed transmission line and the opening increases, electromagnetic coupling between the transmission line and the opening becomes weak, and the antenna characteristics may deteriorate.

In general, according to one embodiment, a wireless apparatus includes a substrate, a first semiconductor chip, a transmission line, a non-conductive layer, a conductive layer and a wire. The first semiconductor chip is arranged on the substrate and includes a circuit which transmits and receives a signal. The transmission line includes a first portion which is formed in at least one of the substrate and the first semiconductor chip. The non-conductive layer seals the first semiconductor chip. The conductive layer covers a surface of the non-conductive layer, an opening being formed in at least a part of the conductive layer. The wire is connected to the first portion so as to extend from the first portion toward the opening and is arranged in a position in which the opening is excited.

Hereinafter, a wireless apparatus according to an embodiment of the present disclosure will be described in detail with reference to the accompanying drawings. In the embodiments that will be described below, structural elements denoted by the same reference numerals perform the same operation, and repetitive description of such elements will be omitted.

### First Embodiment

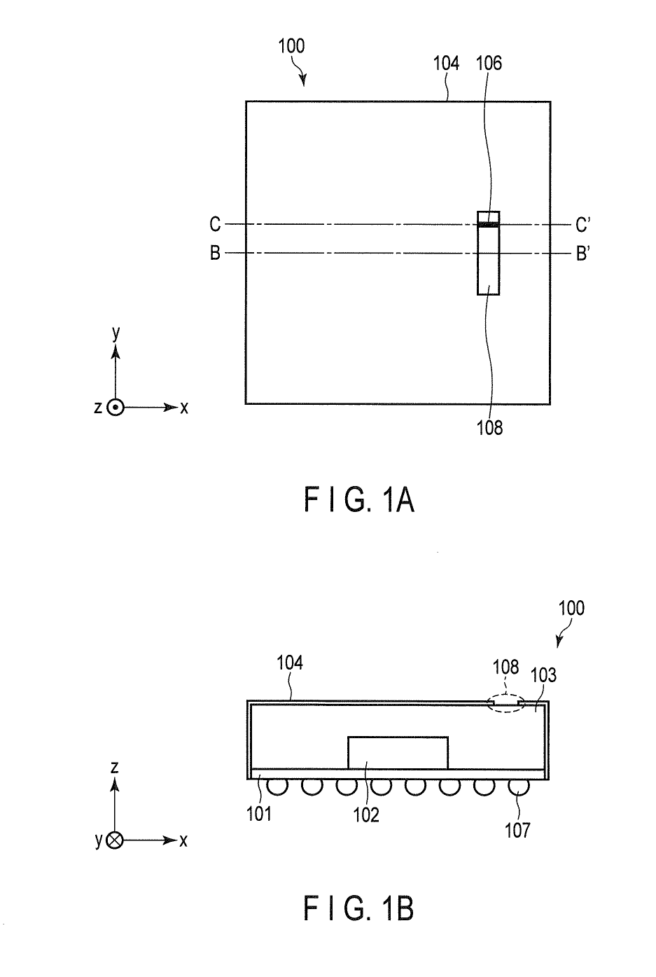

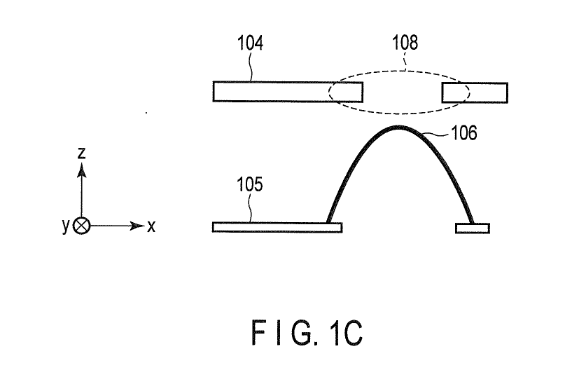

A wireless apparatus according to a first embodiment will be described with reference to FIGS. 1A, 1B, and 1C. FIG. 1A is a top view of the wireless apparatus viewed from the z-axis direction, and FIG. 1B is a cross-sectional view of the wireless apparatus cut along the segment B-B′ of FIG. 1A and viewed from the y-axis direction. FIG. 1C is a cross-sectional view of the wireless apparatus cut along the segment C-C′ of FIG. 1A and viewed from the y-axis direction.

A wireless apparatus 100 according to the first embodiment includes a circuit substrate 101, a semiconductor chip 102, a sealing resin 103, a conductive film 104, an antenna-feed transmission line 105, a bonding wire 106 and a terminal 107. The wireless apparatus 100 is also referred to as a semiconductor package.

The circuit substrate 101 is a substrate on which an elements such as the semiconductor chip 102 is arranged, and a circuit pattern of wiring and a ground, for example, is formed on a first surface of the circuit substrate 101. Although not shown, components such as a chip capacitor, a resistance, an inductor, and an IC may be mounted on the circuit substrate 101.

The semiconductor chip 102 is formed of a semiconductor substrate formed of a material such as silicon, silicon germanium, and gallium arsenide, for example, and is obtained by forming a metal pattern using copper, aluminum, gold, or the like inside or on a surface layer of the semiconductor substrate. The semiconductor chip 102 is stacked on the first surface of the circuit substrate 101, and is electrically connected to the wiring and the ground of the circuit substrate 101 via a bonding wire, a bump, or the like. The semiconductor chip 102 includes a transmission/reception circuit configured to transmit and receive signals.

The semiconductor chip 102 may be a dielectric substrate, a magnetic substrate, a metal, or a combination thereof. Further, the semiconductor chip 102 may be formed of a chip size package (CSP). FIG. 1B shows a case where one semiconductor chip 102 is provided, but the number of the semiconductor chips 102 is not limited to one, and may be more than one. Further, the semiconductor chips 102 may be stacked on one another or arranged side by side.

The sealing resin 103 is formed of a thermosetting molding material, formed mainly of an epoxy resin, added with a silica filler or the like, for example, and is filled onto the first surface of the circuit substrate 101, in order to protect the semiconductor chip 102. The sealing resin 103 is an example of a non-conductive layer, and the material forming the non-conductive layer is not limited to a resin and other non-conductive materials or insulating materials may be used.

The conductive film 104 is a film formed of a conductor, and covers a surface of the sealing resin 103. Further, the conductive film 104 is formed so as to cover the sealing resin 103 and a part of the conductor covering the sealing resin 103 is made open. In the present embodiment, the part of the conductive film 104 that is made open is called an opening 108. In the example of FIG. 1A, a case is shown where one opening 108 is provided, but the number of the openings 108 is not limited to one, and may be more than one.

The antenna-feed transmission line 105 is a transmission line for feeding power, and is arranged in at least one of the circuit substrate 101 and the semiconductor chip 102.

The bonding wire 106 is a wire formed of a conductor, and is connected to the antenna-feed transmission line 105.

The terminal 107 is formed of solder balls, for example, and is a conductor arranged on a second surface facing the first surface of the circuit substrate 101 and designed to connect with other substrates, devices, and the like.

Next, an arrangement example of the bonding wire 106 will be described with reference to FIGS. 1A and 1C.

As shown in FIG. 1C, one terminal of the bonding wire 106 is connected to the antenna-feed transmission line 105 in the circuit substrate 101, and is formed in an arch-like shape so as to extend from the antenna-feed transmission line 105 toward the opening 108 of the conductive film 104. That is, the bonding wire 106 is formed so as to be a part of the antenna-feed transmission line 105 in a position close to the opening 108.

The bonding wire 106 is arranged in a position facing the opening 108, so as to excite the opening 108. The opening 108 is shown in FIG. 1A in an approximately rectangular shape, and is formed such that the bonding wire 106 becomes approximately orthogonal to a longitudinal direction of the opening 108 when the side of the circuit substrate 101 is viewed from the opening 108. When the length of the opening 108 in the longitudinal direction is set to approximately half the wavelength of a desired frequency used for communications, the bonding wire 106 formed so as to be approximately orthogonal to the longitudinal direction of the opening 108 operates as an excitation element of the opening 108, and the opening 108 operates as a slot antenna. Thereby, the opening 108 receives power fed by the bonding wire 106 by electromagnetic coupling, and is capable of radiating or receiving electromagnetic waves of a desired frequency efficiently. By changing the shape of the opening 108, it is also possible to cause the opening 108 to operate as a slot loop antenna or a notch antenna.

Since the bonding wire 106 is formed in an arch-like shape so as to extend from an upper surface of the circuit substrate 101 toward the opening 108, the distance between the opening 108 and the excitation element decreases, compared to the case where an antenna-feed transmission line on a circuit substrate or an antenna-feed transmission line on a semiconductor chip operates as an excitation element. Thereby, the opening and the excitation element are strongly electromagnetically coupled, and the antenna characteristics are improved. In the example of FIG. 1A, the bonding wire 106 is formed in an arch-like shape, but may be formed in other shapes, such as a U-shape, such that the bonding wire 106 becomes close to the opening 108. Further, the longitudinal direction of the opening 108 and the bonding wire 106 are approximately orthogonal, but may be obliquely crossed at a certain angle, e.g., at an acute angle.

The above-described conductive film 104 should desirably be formed of a conductive layer formed of a conductor, a conductive resin, or the like using a metal having a low resistance in order to prevent leakage of unnecessary electromagnetic waves radiated from the semiconductor chip 102. For example, a metal formed of copper, silver, nickel, and the like, or a conductive resin containing copper, silver, or the like may be used as the conductive film 104. The thickness of the conductive film 104 should desirably be set on the basis of the resistivity of the material of the conductive film. For example, the thickness of the conductive film 104 should desirably be set such that a sheet resistance value, which is a value obtained by dividing the resistivity of the conductive film 104 by the thickness of the conductive film 104, becomes 0.5Ω or less. By thus setting the sheet resistance value of the conductive film 104 to be 0.5Ω or less, it is possible to prevent leakage of unnecessary electromagnetic waves in a reproducible manner.

Further, by connecting the conductive film 104 and the ground of the circuit substrate 101 with a low resistance, a high shielding effect is obtained. In the example of FIGS. 1A and 1B, the conductive film 104 contacts a side surface of the circuit substrate 101, and is connected to a ground (not shown) of the circuit substrate 101 on the side surface.

Further, the semiconductor package shown in FIGS. 1A, 1B, and 1C is a ball grid array (BGA) package including the terminal 107 formed of solder balls on a second surface of the circuit substrate 101. The semiconductor package, however, is not limited thereto and may be other types of packages or a module formed of a semiconductor chip and a substrate.

In a part of the circuit substrate 101 covered with the sealing resin 103, other components (not shown) such as a chip capacitor, an IC, and the like may be mounted, as well as the semiconductor chip 102. Further, the shape of the semiconductor chip 102 and the semiconductor package shown in FIGS. 1A and 1B is a square, but is not limited thereto and may be a rectangle, a polygon other than a rectangle, a circle, or other complex shapes.

According to the first embodiment described above, when the opening operates as a slot antenna and the bonding wire operates as an excitation element, by forming the bonding wire in an arch-like shape so as to decrease the distance between the opening and the bonding wire, the coupling between the slot and the excitation element is improved, and electromagnetic waves can be radiated and received at a desired frequency efficiently.

### Second Embodiment

In general, in order to reduce deterioration in shield amount of a conductive film when an opening is formed, it is necessary to form the opening in a position apart from a semiconductor chip, which is the source of noise. When the opening is positioned directly above a semiconductor chip, electromagnetic waves can be radiated by coupling between a transmission line provided on the semiconductor chip and the opening, but when the opening is away from directly above the semiconductor chip, the electromagnetic coupling becomes weak.

To address this, in a wireless apparatus according to a second embodiment, one end of a bonding wire which operates as an excitation element is connected to an antenna-feed transmission line on a circuit substrate. Thereby, the opening and the bonding wire are strongly electromagnetically coupled, and the antenna characteristics are improved.

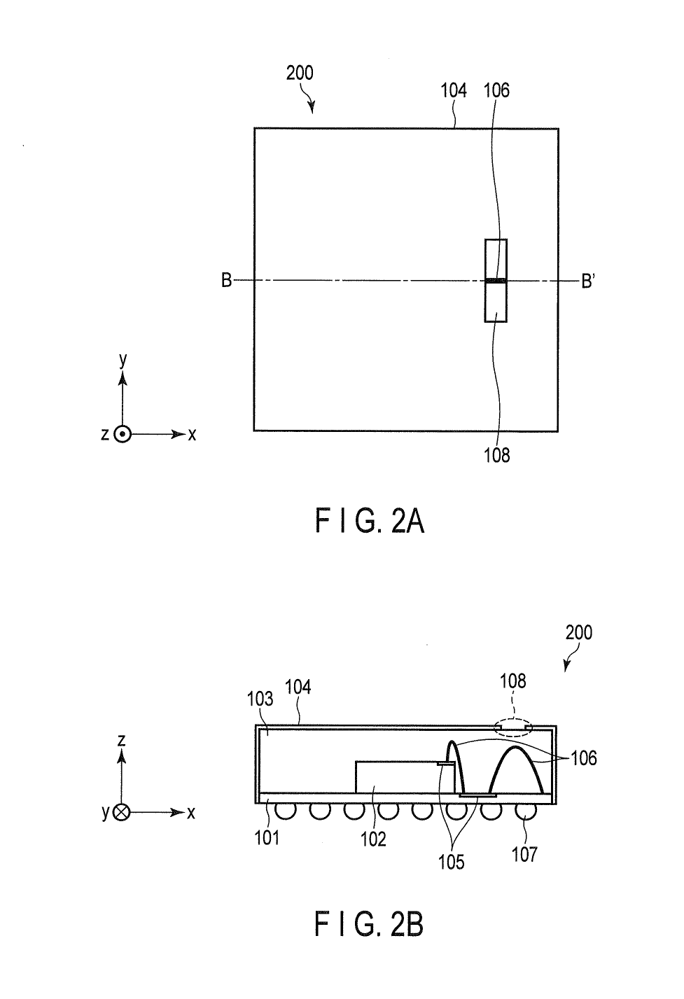

The wireless apparatus according to the second embodiment will be described with reference to FIGS. 2A and 2B.

FIG. 2A is a top view of the wireless apparatus viewed from the z-axis direction, and FIG. 2B is a cross-sectional view of the wireless apparatus cut along the segment B-B′ of FIG. 2A and viewed from the y-axis direction.

A wireless apparatus 200 according to the second embodiment comprises a circuit substrate 101, a semiconductor chip 102, a sealing resin 103, a conductive film 104, an antenna-feed transmission line 105, a bonding wire 106, and a terminal 107.

Since the wireless apparatus 200 according to the second embodiment is the same as the wireless apparatus 100 according to the first embodiment except for the connection position of the bonding wire, detailed description of the wireless apparatus 200 will be omitted.

In the second embodiment, one end of the bonding wire 106 formed in an arch-like shape is connected to the antenna-feed transmission line 105 arranged on the circuit substrate 101, and the bonding wire 106 forms a part of the antenna-feed transmission line.

An opening 108 receives power fed by the bonding wire 106 by electromagnetic coupling, and radiates and receives desired electromagnetic waves to and from the opening. The bonding wire 106 operates as an excitation element, as in the first embodiment. Since the bonding wire 106 is formed in an arch-like shape, the distance between the opening and the excitation element (bonding wire) decreases, compared to the case where the transmission line on the circuit substrate 101 operates as an excitation element, and hence strong electromagnetic coupling is obtained.

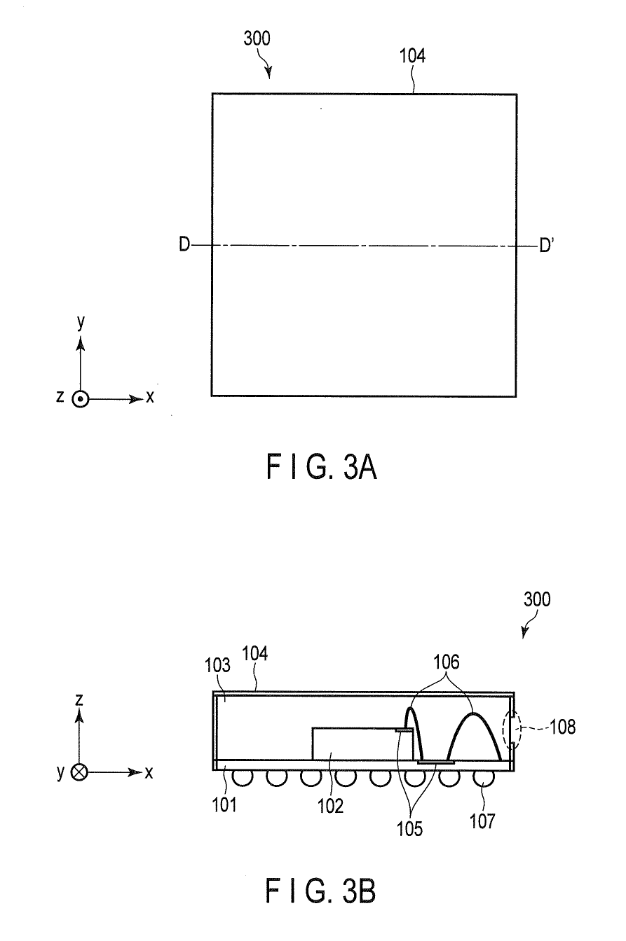

Next, another example of the wireless apparatus according to the second embodiment will be described with reference to FIGS. 3A and 3B.

FIG. 3A is a top view of a wireless apparatus 300 viewed from the z-axis direction, and FIG. 3B is a cross-sectional view of the wireless apparatus cut along the segment B-B′ of FIG. 3A and viewed from the y-axis direction.

FIGS. 3A and 3B illustrate an example in which an opening 108 is formed in a part of a conductive film 104 that covers a side surface part of a sealing resin 103. In this example, since the distance between the opening 108 and an antenna-feed transmission line 105 on a circuit substrate 101 also increases, the coupling becomes weak and the antenna characteristics deteriorate.

By arranging a bonding wire 106 in a position opposite to the opening 108, as shown in FIG. 3B, the antenna characteristics are improved. In the example of FIG. 3B, electromagnetic waves are radiated in a front direction of the side surface in which the opening 108 is formed.

As shown in FIGS. 3A and 3B, by arranging the bonding wire 106 connected to the antenna-feed transmission line 105 in a position in which the distance from one of the side surfaces of the package and the distance from the other side surface of the package are approximately equal (e.g., the center in the y-axis direction of FIG. 3A, i.e., on the segment D-D′), it is possible to change the radiation direction merely by changing the position of the opening using a common semiconductor package in which a surface of a sealing resin is coated with a conductive film. For example, when an L-shaped opening is formed so as to extend from an upper surface to a side surface of a package, the obliquely upward direction of the semiconductor package from the opening can be the radiation direction of electromagnetic waves.

According to the second embodiment described above, when an opening is formed in a position apart from the semiconductor chip as the source of noise, by forming an arch with a bonding wire and decreasing the distance between the opening and the bonding wire, the antenna characteristics are improved, and desired electromagnetic waves can be radiated and received efficiently.

### Third Embodiment

A wireless apparatus according to a third embodiment is different from the wireless apparatuses of the above-described embodiments in that one end of a bonding wire which operates as an excitation element is connected to an antenna-feed transmission line on a semiconductor chip.

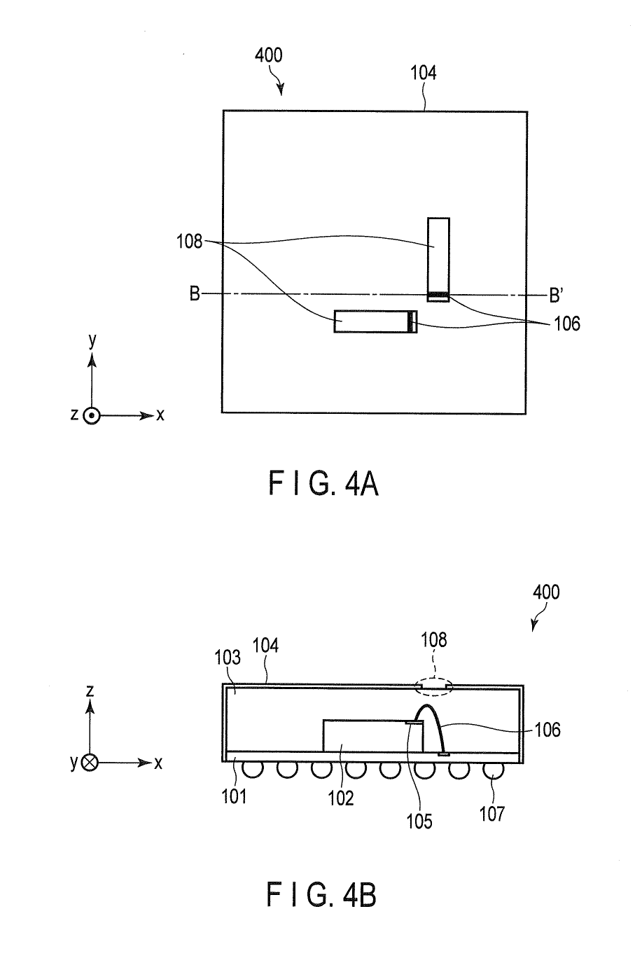

The wireless apparatus according to the third embodiment will be described with reference to FIGS. 4A and 4B. FIG. 4A is a top view of the wireless apparatus viewed from the z-axis direction, and FIG. 4B is a cross-sectional view of the wireless apparatus cut along the segment B-B′ of FIG. 4A and viewed from the y-axis direction.

Since a wireless apparatus 400 according to the third embodiment is the same as the wireless apparatus 100 according to the first embodiment except for the connection position of the bonding wire, detailed description of the wireless apparatus 400 will be omitted.

As shown in FIGS. 4A and 4B, one end of a bonding wire 106 is connected to an antenna-feed transmission line 105 of a semiconductor chip 102, and the other end of the bonding wire 106 is connected to a metal pattern of a circuit substrate 101. This is effective when the requested shield amount is relatively small and the opening 108 can be made closer to the semiconductor chip 102. Further, this structure can be easily manufactured in a usual bonding process that connects the semiconductor chip 102 and the circuit substrate 101.

In the example of FIG. 4A, two openings 108 are formed, but the number of the openings 108 is not limited to two, and may be one or more than two.

By adjusting the driving amplitude and the phase of each of the two openings of FIG. 4A, it is possible to radiate linearly-polarized waves, circularly-polarized waves, and elliptically-polarized waves.

According to the third embodiment described above, when the requested shield amount is relatively small, by connecting a bonding wire to an antenna-feed transmission line on a semiconductor chip, the distance between the opening and the bonding wire can be decreased, compared to the case where a bonding wire is connected to a transmission line on a circuit substrate, and electromagnetic waves of a desired frequency can be radiated and received efficiently.

### Fourth Embodiment

The wireless apparatus according to a fourth embodiment is different from the wireless apparatuses according to the above-described embodiments in that one end of a bonding wire which operates as an excitation element is connected to an antenna-feed transmission line on a semiconductor chip and the other end is connected to a metal pattern on the semiconductor chip.

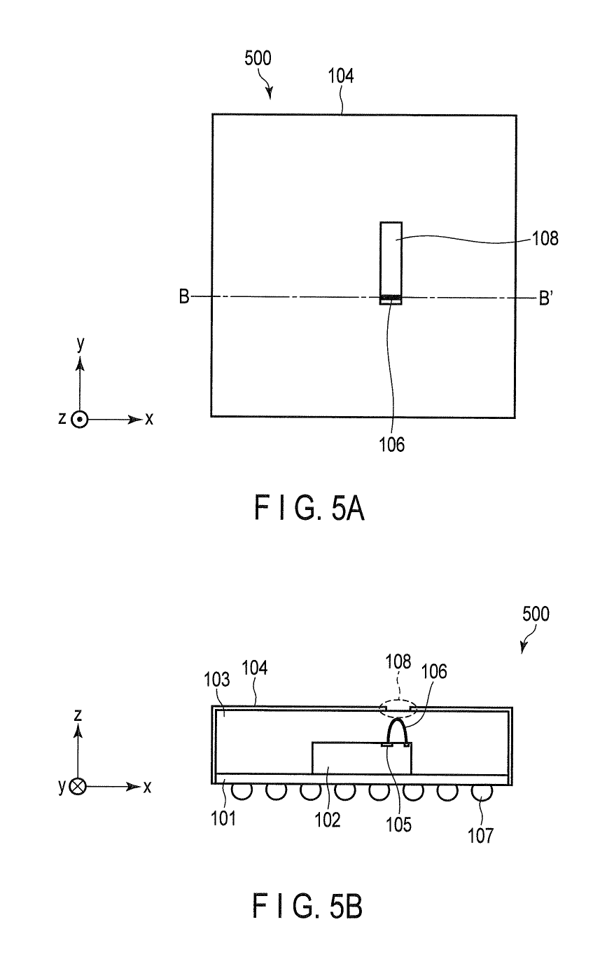

The wireless apparatus according to the fourth embodiment will be described with reference to FIGS. 5A and 5B. FIG. 5A is a top view of the wireless apparatus viewed from the z-axis direction, and FIG. 5B is a cross-sectional view of the wireless apparatus cut along the segment B-B′ of FIG. 5A and viewed from the y-axis direction.

Since a wireless apparatus 500 according to the fourth embodiment is the same as the wireless apparatus 100 according to the first embodiment except for the connection position of a bonding wire, detailed description of the wireless apparatus 500 will be omitted.

In the fourth embodiment, a case is assumed where the requested shield amount is relatively small, and at least a part of an opening 108 is included in a region of an upper surface of a sealing resin 103 directly above a semiconductor chip 102. As shown in FIG. 5B, one end of a bonding wire 106 is connected to an antenna-feed transmission line 105 of the semiconductor chip 102, and the other end of the bonding wire 106 is connected to a metal pattern of the semiconductor chip 102. With this structure, as in the above-described embodiments, it is possible to decrease the distance between the opening 108, which operates as a slot, and the bonding wire 106, which operates as an excitation element.

According to the above-described fourth embodiment, when the requested shield amount is relatively small, by connecting one end of a bonding wire that operates as an excitation element to an antenna-feed transmission line of a semiconductor chip and connecting the other end to a metal pattern of the semiconductor chip, so as to decrease the distance between the opening and the bonding wire, the antenna characteristics are improved, and electromagnetic waves of a desired frequency can be radiated and received efficiently.

### Fifth Embodiment

The wireless apparatus according to a fifth embodiment is different from the above-described embodiments in that a mount is arranged on a circuit substrate and adjustment is performed such that a position in which the intensity of a current flowing through a bonding wire becomes maximum is made close to an opening.

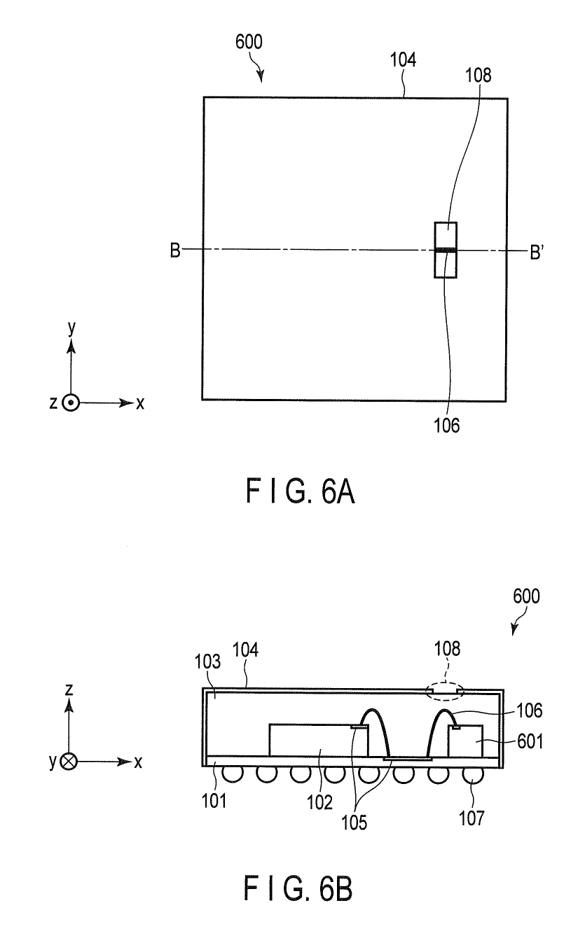

The wireless apparatus according to the fifth embodiment will be described with reference to FIGS. 6A and 6B. FIG. 6A is a top view of the wireless apparatus viewed from the z-axis direction, and FIG. 6B is a cross-sectional view of the wireless apparatus cut along the segment B-B′ of FIG. 6A and viewed from the y-axis direction.

A wireless apparatus 600 according to the fifth embodiment is the same as the wireless apparatus 100 according to the first embodiment in structure except that a mount 601 is provided and the connection position of a bonding wire is different.

The mount 601 is formed of a dielectric substrate, a magnetic substrate, a metal, or a combination thereof, and is arranged on the circuit substrate 101. The mount 601 includes a metal pattern.

In order to efficiently excite the opening 108, the intensity of a current flowing through a transmission line (bonding wire) needs to be maximum in a position opposite to the opening 108.

More specifically, the point at a distance of a sum of a quarter wavelength and integral multiples of a half wavelength of a used frequency from the other end of the bonding wire 106, which is opposite to one end of the bonding wire 106 connected to an antenna-feed transmission line and which is connected to the metal pattern, should be provided in a position closest to the opening 108. From the viewpoint of manufacturing and frequency band, the point at a distance of a quarter wavelength from the other end of the bonding wire 106 connected to the metal pattern can be easily arranged in a position closest to the opening 108.

When an arch is formed with the bonding wire 106 only from an upper surface of the circuit substrate 101, however, since the point at a distance of a quarter wavelength from the other end of the bonding wire 106 connected to the metal pattern is included in a leading edge of the arch, there are cases where the opening 108 cannot be excited efficiently.

To address this, as shown in FIG. 6B, by arranging a mount 601 including a metal pattern on the circuit substrate 101 and connecting one end of the bonding wire 106 to the metal pattern on the mount 601, the point at a distance of a quarter wavelength from a termination of the bonding wire connected to the metal pattern can be arranged in a position closest to the opening 108 so as to be opposed thereto. As a result, the electromagnetic coupling between the opening 108 and the bonding wire 106 can be improved.

In FIG. 6B, the other end of the bonding wire 106, which is opposite to one end connected to the mount 601 of the bonding wire 106, is connected to the antenna-feed transmission line 105 on the semiconductor chip 102, but may be connected to the antenna-feed transmission line 105 on the circuit substrate 101.

Further, the mount 601 may be replaced with a semiconductor chip. It is also possible to provide a multi-chip package including a plurality of semiconductor chips, form a bonding wire between the semiconductor chips, and form an opening in a position opposite to the bonding wire.

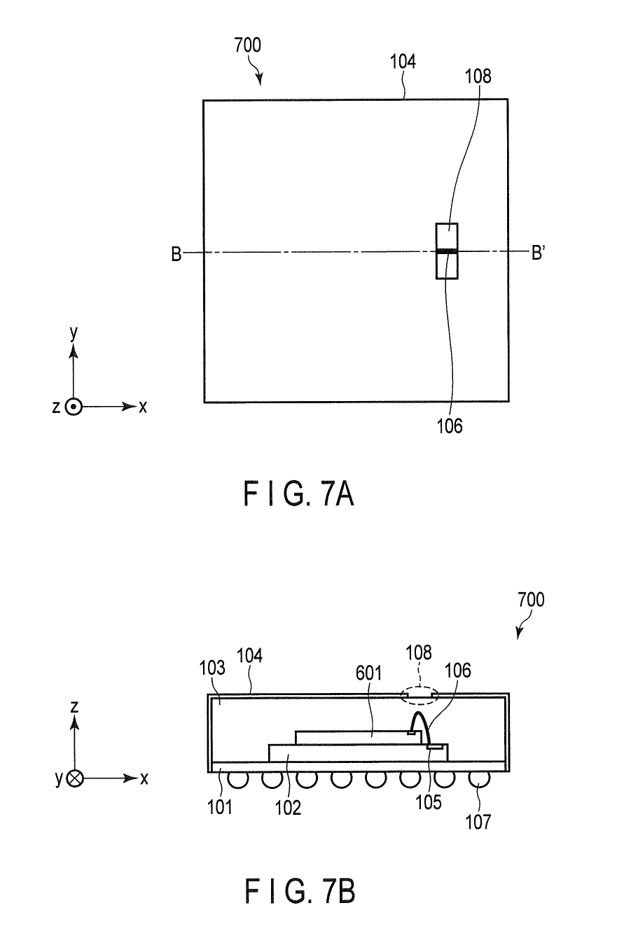

Next, another example of the wireless apparatus according to the fifth embodiment will be described with reference to FIGS. 7A and 7B.

FIG. 7A is a top view of a wireless apparatus 700 viewed from the z-axis direction, and FIG. 7B is a cross-sectional view of the wireless apparatus cut along segment B-B′ of FIG. 7A and viewed from the y-axis direction.

FIGS. 7A and 7B illustrate an example in which a mount 601 is arranged on a semiconductor chip 102. The mount 601 is stacked on the semiconductor chip 102 when there is no space for arranging the mount 601 on the circuit substrate 101.

In this case, as shown in FIG. 7B, by arranging a bonding wire 106 in a position opposite to an opening 108, the antenna characteristics are improved.

In FIGS. 7A and 7B, the mount 601 is stacked on the semiconductor chip 102, but may be stacked on other mount components provided in the wireless apparatus 700.

According to the fifth embodiment described above, by connecting one end of a bonding wire to a metal pattern on a mount and making the point at a distance of a sum of a quarter wavelength and integral multiples of a half wavelength from a termination of a bonding wire connected to the metal pattern close to the opening so as to be opposed thereto, the antenna characteristics are improved, and electromagnetic waves of a desired frequency can be radiated and received efficiently.

### Sixth Embodiment

A sixth embodiment is different from the above-described embodiments in that both ends of a bonding wire are connected to an antenna-feed transmission line and a metal pattern on a mount.

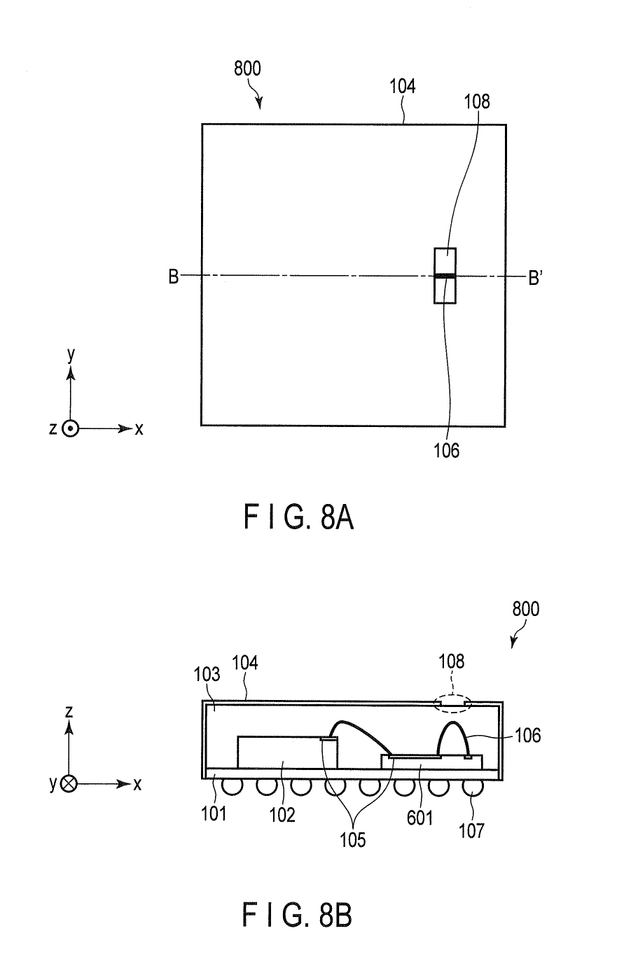

A wireless apparatus according to the sixth embodiment will now be described with reference to FIGS. 8A and 8B. FIG. 8A is a top view of the wireless apparatus viewed from the z-axis direction, and FIG. 8B is a cross-sectional view of the wireless apparatus cut along the segment B-B′ of FIG. 8A and viewed from the y-axis direction.

A wireless apparatus 800 according to the sixth embodiment is the same as the wireless apparatus 600 according to the fifth embodiment except for the connection position of a bonding wire.

One end of a bonding wire 106 is connected to an antenna-feed transmission line 105 of a mount 601, and the other end of the bonding wire 106 is connected to a metal pattern of the mount 601. With this structure, as in the above-described embodiments, the distance between the opening 108 and the bonding wire 106 decreases, and the point at a distance of a quarter wavelength from a termination can be made close to the opening 108. In addition, since the distance between the opening 108 and the bonding wire 106 can be changed without changing the length of the bonding wire 106 by changing the height of the mount 601 from a circuit substrate 101, adjustments can be performed easily.

According to the sixth embodiment described above, by connecting both ends of a bonding wire to a mount, the distance between the opening and the bonding wire can be easily adjusted, and desired electromagnetic waves can be radiated and received efficiently.

### Seventh Embodiment

It is also possible to use the wireless apparatuses according to the first to sixth embodiments in a wireless system. An example of a wireless system including the wireless apparatus according to the first to sixth embodiments will be described. The wireless system is a system configured to transmit and receive data, images, and moving images, and includes the above-described wireless apparatus.

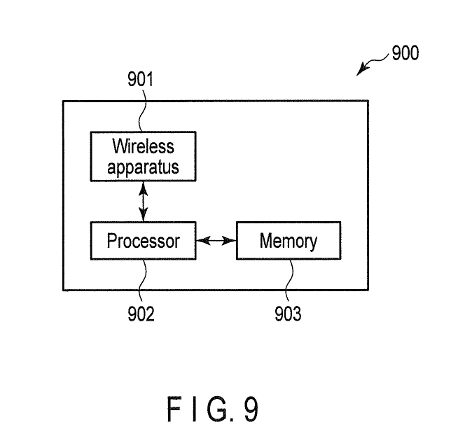

A wireless system according to a seventh embodiment will be described with reference to the block diagram shown in FIG. 9.

A wireless system 900 shown in FIG. 9 includes a wireless apparatus 901, a processor 902, and a memory 903.

The wireless apparatus 901 performs transmission and reception of data to and from the outside. The wireless apparatus according to any of the first to sixth embodiments may be used.

The processor 902 processes data received from the wireless apparatus 901, or data to be transmitted to the wireless apparatus 901.

The memory 903 receives data from the processor 902, and stores the data.

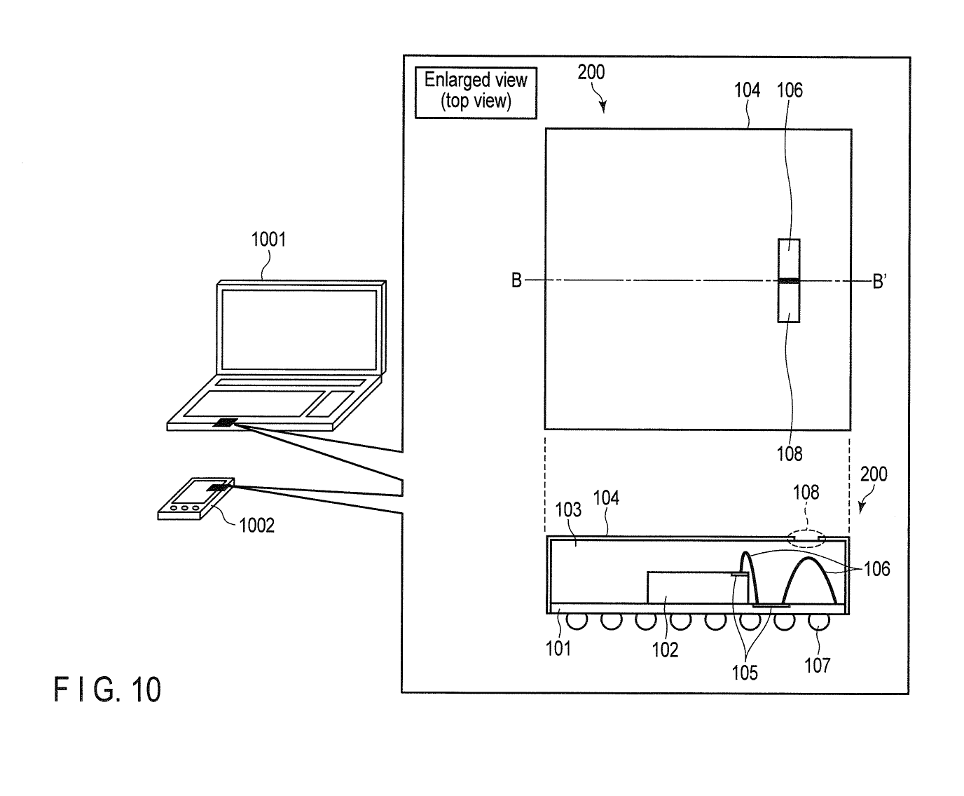

An example of a wireless system including the wireless apparatus 901 will be described with reference to FIG. 10.

In this case, the wireless system is a note PC 1001 and a portable terminal 1002, by way of illustration. Each of the note PC 1001 and the portable terminal 1002 includes a wireless apparatus 801 inside or outside, and performs data communications via the wireless apparatus 1001 using a frequency of a millimeter wave band, for example. In the example of FIG. 10, the wireless apparatus 200 according to the second embodiment is shown as an example of the wireless apparatus, but the wireless apparatus is not limited thereto and may be any wireless apparatus according to the other embodiments.

By arranging the wireless apparatus 901 mounted on the note PC 1001 and the wireless apparatus 901 mounted on the portable terminal 1002 such that the directions in which the directivity of the antenna becomes strong are opposed to each other, transmission and reception of data can be performed efficiently.

In the example of FIG. 10, the note PC 1001 and the portable terminal 1002 are shown, but the wireless system is not limited thereto, and the wireless apparatus may be mounted on other systems such as a TV, a digital camera, and a memory card.

According to the seventh embodiment described above, by mounting the above-described wireless apparatus on a communication system for performing data communications, such as a note PC and a portable terminal, data transmission and reception can be performed efficiently while reducing the effect of noise.

### Eighth Embodiment

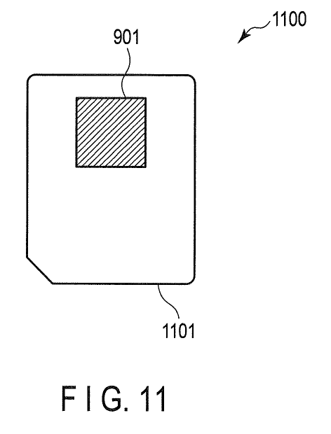

An example of a wireless system in which a wireless apparatus is mounted on a memory card is shown in FIG. 11.

As shown in FIG. 11, a memory card 1100 includes a wireless apparatus 901 and a memory card main body 1101, and is capable of performing wireless communications with a note PC, a portable terminal, a digital camera, and the like via the wireless apparatus 901.

Since the memory card 1100 includes the wireless apparatus 901, the memory card 1100 is capable of performing wireless communications with the note PC, the portable terminal, the digital camera, and the like.

According to the eighth embodiment described above, by mounting the wireless apparatus, which performs wireless data communications with a note PC, a portable terminal, or the like, on a memory card, it is possible to provide a memory card equipped with a wireless communication function that is less affected by noise, and to perform transmission and reception of data efficiently.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A wireless apparatus, comprising:
a substrate;
a first semiconductor chip arranged on the substrate and including a circuit which transmits and receives a signal;
a transmission line including a first portion which is formed in at least one of the substrate and the first semiconductor chip;
a non-conductive layer sealing the first semiconductor chip;
a conductive layer covering a surface of the non-conductive layer, an opening being formed in at least a part of the conductive layer; and
a wire connected to the first portion so as to extend from the first portion toward the opening and being arranged in a position in which the opening is excited.

2. The apparatus according to claim 1, wherein the opening is rectangular, the wire is arranged in a position close to the opening such that a first distance between the wire and the opening becomes smaller than a second distance and a third distance, and the wire is formed to be approximately orthogonal to a longitudinal direction of the opening when the substrate is viewed from the opening, the second distance being a distance between the first semiconductor chip and the opening, the third distance being a distance between the substrate and the opening.

3. The apparatus according to claim 1, wherein the first portion is formed in the first semiconductor chip, one end of the wire is connected to the first portion.

4. The apparatus according to claim 1, wherein the first portion is formed in the substrate, one end of the wire is connected to the first portion.

5. The apparatus according to claim 1, further comprising a metal pattern different from the transmission line, wherein the first portion is formed in the first semiconductor chip, one end of the wire is connected to the first portion, and the other end of the wire is connected to the metal pattern.

6. The apparatus according to claim 1, further comprising a mount including a metal pattern and being arranged on at least one of the substrate and the first semiconductor chip, wherein one end of the wire is connected to the first portion, the other end of the wire is connected to the metal pattern, and a part of the wire where a current intensity flowing through the wire becomes maximum is arranged in a position closest to the opening.

7. The apparatus according to claim 6, wherein the part of the wire arranged in the position closest to the opening is a part at a distance of a sum of a quarter wavelength of a used frequency and integral multiples of a half wavelength of the used frequency, from the other end.

8. The apparatus according to claim 1, further comprising a mount including a second portion of the transmission line and a metal pattern and being arranged on the substrate,
wherein one end of the wire is connected to the second portion, and the other end of the wire is connected to the metal pattern.

9. The apparatus according to claim 6, wherein the mount is a second semiconductor chip different from the first semiconductor chip.

10. A wireless system communicating with an outside device, the wireless system comprising:
the wireless apparatus according to claim 1;
a processor configured to process data relating to wireless communications which are performed by the wireless apparatus; and
a memory configured to store data relating to the processed data.

11. A memory card communicating with an outside device, the memory card comprising the wireless apparatus according to claim 1.
